(19) United States
(12) Patent Application Publication
(10) Pub. No.: US 2010/0012171 A1
(43) Pub. Date: Jan. 21, 2010

(54) HIGH EFFICIENCY CONCENTRATING PHOTOVOLTAIC MODULE WITH REFLECTIVE OPTICS

(76) Inventor: Danny F. Ammar, Windermere, FL (US)

Correspondence Address: Danny F. Ammar, Suite 216, 8815 Conroy Windermere Rd, Orlando, FL, 32835, US

(21) Appl. No.: 12/535,116

(22) Filed: Aug. 4, 2009

Related U.S. Application Data
(63) Continuation-in-part of application No. 12/043,018, filed on Mar. 5, 2008.

(51) Int. Cl. H01L 31/052; H01L 31/00

(52) U.S. Cl. 136/246; 136/259

(57) ABSTRACT

A Concentrating Photovoltaics (CPV) module includes light weight housing, a number of Cassegrain type reflective solar concentrators, a number of multi-junction solar cells and a novel heat spreading system. The primary and secondary reflectors focus the sun over 500 times to maximize the amount of photons collected by the solar cells and converted to electricity. A newly designed soft board material provides coefficient of thermal expansion (CTE) matched carrier for the solar cells and an efficient electrical connectivity method. The carrier board is attached to a specially formulated heat spreader that is specially formulated to conduct heat longitudinally away from the solar cells. The combination of the above creates CPV modules with the highest efficiency and lowest cost per Watt.

### CROSS-REFERENCE TO RELATED APPLICATIONS

This application is a continuation-in-part of U.S. application Ser. No. 12/043,018, filed Mar. 3, 2008 and entitled “High Efficiency Concentrating Photovoltaic Module Method and Apparatus”.

### FIELD OF THE INVENTION

The present invention relates to the field of solar power conversion system using Concentrating Photovoltaics (CPV). More specifically, the present invention includes an array of light weight primary and secondary reflective collectors for concentrating sun rays onto an array of solar cells which generate electric power.

### BACKGROUND OF THE INVENTION

The idea of concentrating sunlight onto a small solar cell had been studied and tried for many years. The primary reason for using concentrators is to be able to use less solar cell material. A concentrator makes use of relatively inexpensive materials such as plastic lenses, or dish reflectors, to capture the solar energy shining on a fairly large area and focus that energy onto a smaller area, where the solar cell is located. Sunlight is composed of particles of solar energy called photons, and when these particles strike a photovoltaic cell, they may be reflected, pass right through, or be absorbed. Only a portion of the absorbed photons provides energy to generate electricity.

There are several advantages in concentrator PV systems, as compared to normal PV systems, including higher output power, higher efficiency and less semiconductor material use. However, there are also several deficiencies in current CPV systems, including long focal lengths optic concentrators resulting in substantial module height and weight, intense heat resulting in reduced solar cell efficiency and reliability or requiring active cooling methods, high Electrical resistance in the cell-to-cell connection results in higher losses and lower efficiency, and high precision sun trackers.

The goal of any solar collection system is to reduce the cost of electricity generated. There are fundamentally two ways to do this, namely, reduce the initial cost of the solar modules, and, to increase system efficiency. Solar module efficiency is dependent upon a number of factors, including, without limitation, the solar cell efficiency, sunlight incident angle effects, collector tracking error, the geometric accuracy of the mirrors to focus light on the solar cells, mirror reflectivity, cleanliness of the mirrors, transmittance of solar energy into the solar cells, and absorption of solar energy by the solar cells. While current PV systems produce electricity at a cost in the range of $0.12 to $0.18 per kilowatt-hour, it is desirable to achieve a cost level of about $0.05 per kilowatt-hour to be more competitive with present fossil-fuel based systems.

Current state-of-the-art in CPV modules, in so far the applicant is aware of at the time of this application, typically are configured in a box like structure, with traditional refractive or reflective optics and low solar-to-electrical conversion efficiency, typically below 24%, due to excessive heat. This invention incorporates newly engineered materials to lower initial cost and to substantially increase solar cell efficiency by quickly spreading the heat away from the solar cells. A low cost coefficient-of-thermal-expansion (CTE) matched soft board acts as a carrier for the solar cells to reduce temperature cycle stress and provides low loss electrical connectivity between cells. Other newly engineered materials used in the current invention include a light weight anisotropic heat spreader made of graphite fibers that conducts heat well longitudinally away from the source and thus minimizing hot spots. Light weight aluminum housing provides a sealed environment for the CPV module at a fraction of the weight of cast housings. The reflective optics used in this invention are unique in that they have shallow focal point and a wide sun acceptance angle, resulting in thinner and more aesthetically pleasing CPV modules. The wider acceptance angle reduces the sun tracker accuracy requirements. All these taken in total result in high CPV module efficiency and low cost per watt of electricity generated.

### SUMMARY OF THE INVENTION

This invention is directed to a concentrating PV module that improves solar conversion efficiency, lowers initial costs, and therefore reduces the overall cost of generating electricity per kilowatt-hour.

One aspect of this invention is predicated on the concept of providing a simple, CPV module comprising one or more reflective sun concentrating units arranged in a construction that is highly modular, easily assembled, and lower in initial cost. In one embodiment, each module includes a light-weight aluminum housing tray that mounts a number of solar collectors having a shape approximating that of a parabola and covered by anti-reflection glass that provides a sealed environment. The focal line of such parabola is coincident with a secondary reflector which receives sunlight incident on the primary collectors and reflects such light onto a solar cell mounted in a fixed position slightly below the primary reflector and substantially concentric to the centerline of the primary collector. The primary collector is supported by a frame to add rigidity, and maintain precise location relative to the secondary reflector and the solar cell. A number of individual collectors may be arranged side-by-side to form a solar module of desired size.

In one embodiment of this invention, each solar concentrating system preferably comprises primary and secondary durable, stamped aluminum collectors with highly reflective surfaces, typically silver metalized, that efficiently reflect incident sunlight many times its normal intensity onto the solar cell.

In one embodiment the solar collectors are protected from the outside environment by an anti-reflection glass with high transmissivity and low reflectivity. The protective glass is also used to support the secondary reflectors, which are permanently bonded to the glass right above the primary reflectors.

In an alternative embodiment, the solar cells are attached, using solder or epoxy, to a uniquely formulated thin printed circuit board (PCB) with a coefficient of thermal expansion (CTE) that is matched the solar cells. The top layer of the PCB includes copper traces, which provide low loss cell-to-cell electrical interconnection, therefore eliminating the need for interconnect wires.

Still another embodiment of this invention is designed to increase efficiency by reducing heat in the solar cells. It has been found that when sun radiation is concentrated, so is the amount of heat produced. Cell efficiencies decrease as temperatures increase, and higher temperatures also threaten the long-term stability of solar cells. Therefore, the solar cells must be kept cool in a concentrator system. In this embodiment, a heat spreader made of graphite fibers, weighing 60% less than aluminum and 82% less than cooper, is bonded to the PCB board. The graphite heat spreaders offer thermal conductivity up to 1500 W/mK as compared to about 200 W/mK for aluminum. The heat spreader of the current invention is anisotropic, conducting heat well along its x and y axes but less in the z-axis. As a result, it conducts the heat longitudinally away from the source and thus reduce temperature rise in the solar cell.

### BRIEF DESCRIPTION OF THE DRAWINGS

Other objects, features and advantages of the present invention will become apparent from the detailed description of the invention which follows, when considered in light of the accompanying drawings.

FIG. 1 is a block diagram of a typical grid-connected photovoltaic solar system.

FIG. 2 shows prior art reflective type solar concentrator.

FIG. 2A shows prior art refractive type solar concentrator.

FIG. 2B shows prior art refractive solar concentrator with curved shaped lens.

FIG. 2C shows prior art solar concentrator module using curved shaped Fresnel lens.

FIG. 2D shows prior art solar concentrator with dome shaped Fresnel lens.

FIG. 3 is a prospective view, partially cutaway, of a high concentration photovoltaic module, typically used with sun tracking, having eighteen concentrator cells.

FIG. 3A is a prospective view of a medium concentration photovoltaic module, typically used in fixed installations, having eighteen concentrator cells.

FIG. 4 shows an example of sun concentrator optics having 2 positive Fresnel lenses.

FIG. 4A shows an example of sun concentrator optics having one Fresnel lens and a secondary flux homogenizer.

FIG. 4B shows a medium concentrator optical system having one negative and one positive Fresnel lens.

FIG. 4C shows an example of low-to-medium concentrator having one dome-shaped Fresnel lens and a flat Fresnel lens.

FIG. 4D shows an isometric view and a cross sectional view of a flux homogenizer.

FIG. 4E shows the secondary reflector/homogenizer ability to widen the sun tracking acceptance angle.

FIG. 5 shows the multi-junction solar cell ability to capture different parts of the light spectrum and thereby achieving such high efficiency.

FIG. 5A shows the solar cells efficiency and electricity generation capacity of Silicon and multi-junction solar cells.

FIG. 6 shows detailed views of the front and back sides of the CTE matched board with expanded views of the solar mounting areas and a cross section of the assembly.

FIG. 6A shows a top view of a 20-cell solar module electrical connectivity of the current invention.

FIG. 7 shows the heat spreading concept of the current invention.

FIG. 7A shows the base plate panel which includes a honeycomb core used for increased regidity and module stiffness.

FIG. 8 is a cross-sectional view (not to scale) of three concentrator cells illustrating the heat spreading method.

FIG. 8A is a cross-sectional view (not to scale) of a single concentrator cell illustrating the double heat-spreader method.

FIG. 9 shows a cross sectional view of a solar cell with a heatsink underneath it and an isometric view of the heatsink.

FIG. 10 shows a top view and an isometric view of heatsinks added to the frame of an 18-cell solar module.

FIG. 11 Shows a cross sectional view of a single solar cell and a top view of an 18-cell module with water cooling option.

FIG. 12 shows an exploded view of the base plate sub-assembly shown the module assembly process.

FIG. 13 shows a prospective view of the module frame shape, which holds the optics and the base plate sub-assemblies.

FIG. 14 shows a prospective view of this invention's reflective-type CPV module with 20 solar cells, of which 2 are removed to show details

FIG. 15 Show a prospective view of the light weight tray enclosure of the current invention.

FIG. 16 shows the Cassegrain configuration of the reflective optics of the current invention.

FIG. 17 shows the primary reflector support frame.

FIG. 18 shows a side view of a single cell of the reflective-type CPV module of the current invention.

### DETAILED DESCRIPTION OF THE INVENTION

The present invention will now be described more fully hereinafter with references to the accompanying drawings, in which preferred embodiments of the invention are shown. This invention may, however, be embodied in many different forms and should not be constructed as limited to the embodiments set forth herein. Rather, these embodiments are provided so that this disclosure will be thorough and complete, and will fully convey the scope of the invention to those skilled in the art. Like numbers refer to like elements throughout.

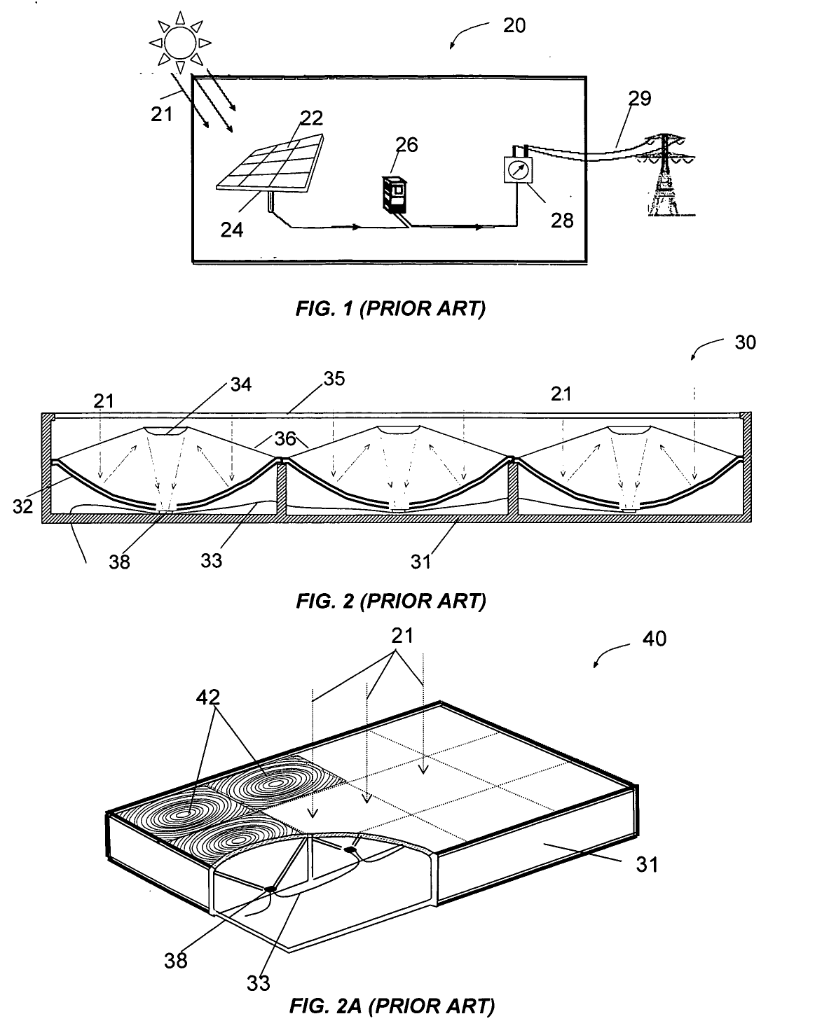

FIG. 1 shows a typical grid-connected concentrated photovoltaic solar system. The solar array 22 consists of one or more CPV modules which convert sunlight 21 into electricity. The sun tracker 24 is a device that rotates in 2-axes to track the sun across the sky throughout the day to keep the sun rays directly on the solar array. It is advantageous for the solar array to be oriented substantially perpendicular to the position of the sun throughout the course of a day in order to maximize the efficiency with which the sunlight is converted to electricity. The DC-AC inverter 26 converts the DC power produced by the solar array into AC power consistent with the voltage and power quality requirements of the utility grid. The power meter 28 measures the amount of electricity being generated and released to the power grid 29. The solar array cost represents around 50 to 60% of the total installed cost of a typical grid-connected Solar Energy System.

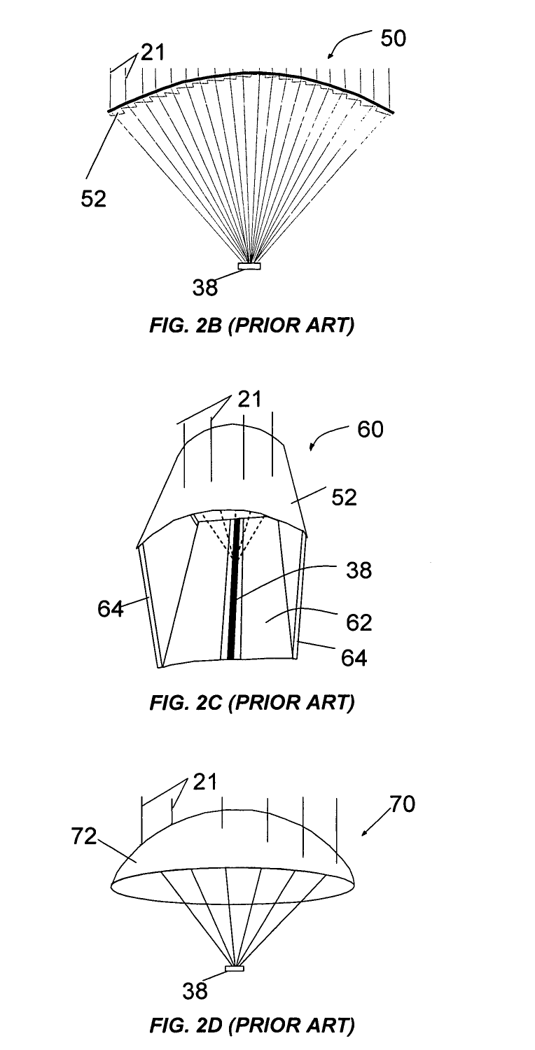

The majority of CPV modules currently in use are of the type depicted in FIGS. 2 and 2A. An array of reflective collectors 32 or refractive lenses 42 are used to concentrate sun rays 21 onto solar cells 38 which convert sun light into electric power. Generally, sun concentration can either be achieved by refractive optics, meaning using lenses, or by reflective collectors typically parabolic in shape. To achieve the desired module output voltage, the solar cells are serially connected using electrical wires 33. The optical concentrator and the solar cells are assembled in a box-like housing 31, typically made out of cast aluminum, which provides protection from the environment and acts as a heat sink. For the CPV module 30, a highly reflective primary parabolic reflector 32 collects the sun rays 11 and directs them to a sub-reflector 34, which is held in place with a bracket 36. The sub-reflector in turn focuses the rays onto the solar cell 38. A top glass cover 35 provides protection from the outside environment while allowing sun rays to pass through.

FIGS. 2B through 2D show prior art refractive solar concentrators with curved and done shaped lenses. In FIG. 2C, the teeth of the lens 52 run in straight rows act as line-focusing concentrators. The sun rays 21 are focused on a long line of solar cells 38, which is mounted on a base plate 62. The base plate and the lens are maintained at a fixed distance relative to each other using the mounting brackets 64. In FIG. 2D, the solar concentrator uses a dome-shaped lens. The lens 72 captures the sun rays 21 from any direction, thereby eliminating the need to track the sun and focuses them on the solar cell 38.

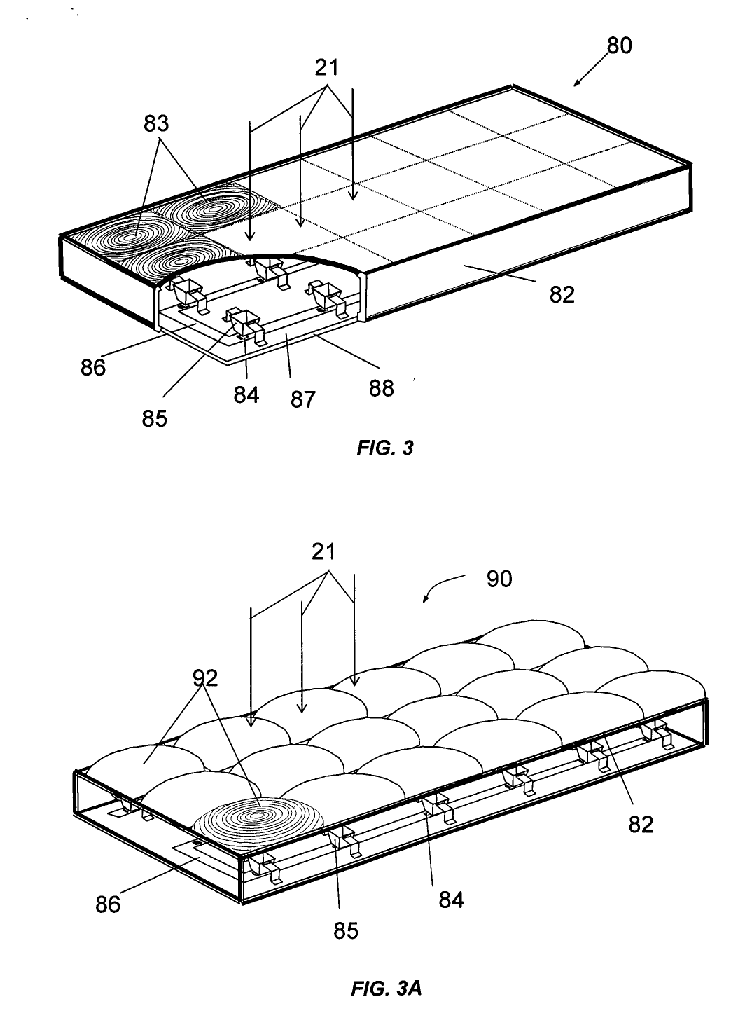

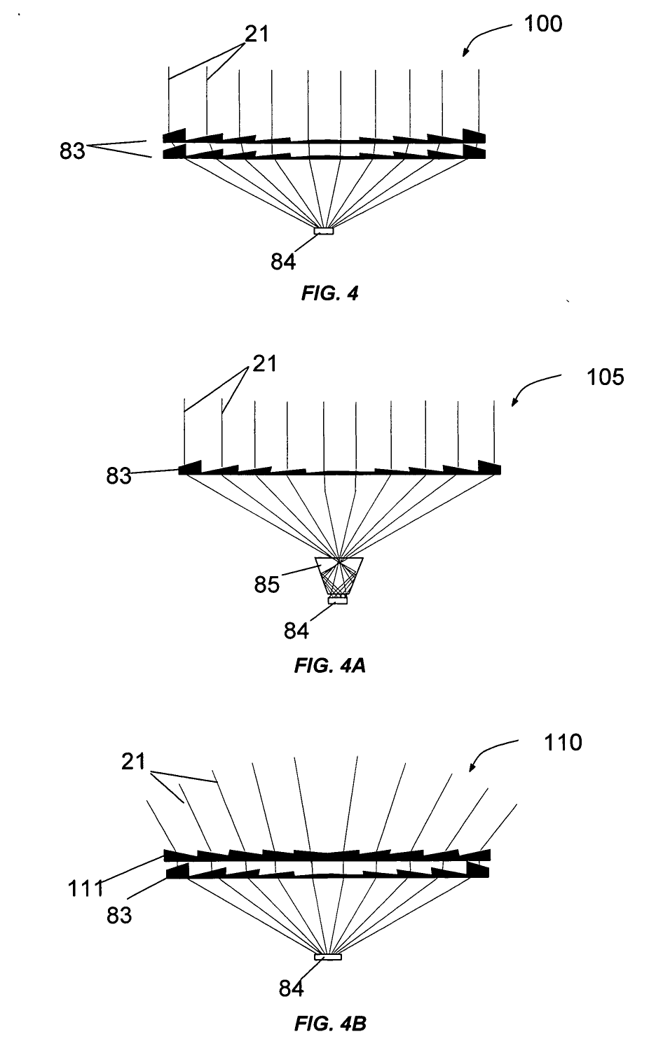

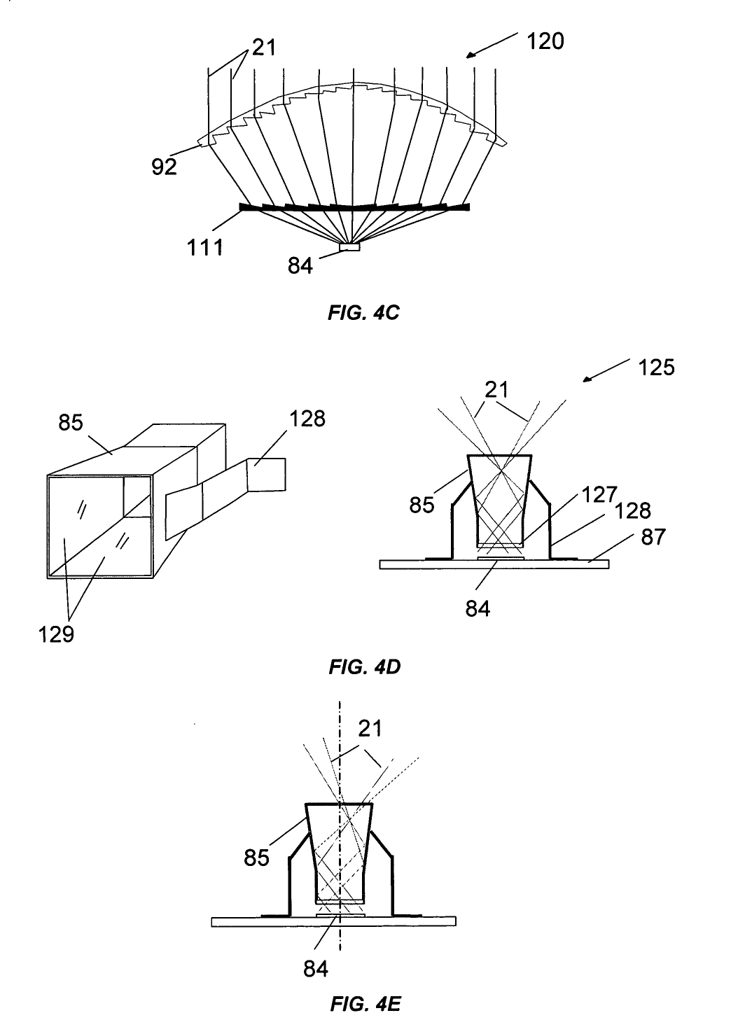

FIGS. 3 through 4E describe refractive-type CPV module that uses lenses to concentrate sun energy.

FIG. 3 shows a prospective view of a high concentration photovoltaic module 80 having 18 concentrator cells held together by a metal frame 82, which provides the required rigidity and strength to be able to mount the module in harsh outdoor environment. It should be understood that although an 18-cell module is illustrated in FIG. 3, any number of solar cells can be used. The metal frame 82 is made-up of low cost extruded aluminum with pockets used to hold the Fresnel lenses, which can be manufactured on a single sheet of acrylic plastic, and the base assembly which includes the solar cells. This module combines the use of multi-junction solar cells 84 with a novel approach to sun concentration using a multiplicity of Fresnel lenses 83 and a reflective or refractive flux homogenizer 85, and unique approaches to heat spreading and electrical loss minimization, to provide high efficiency solar energy conversion to electricity. Each of the Fresnel lenses 83 is made up of one or more lenses bounded together to form the basic concentrating optics for each cell, while minimizing the focal length and thereby reducing the module thickness. The lens structure will be discussed in detail in the next few paragraphs. The multiplicity of Fresnel lenses 83 are used to collect the sun rays 21 and focuses them up to 1000 times into a secondary concentrator 85, which create a homogenous flux for the solar cells 84. The solar cells 84 are made of multi-junction semiconductor material, which provides up to 40% efficiency in solar energy conversion to electricity. The solar cells 84 are mounted on a specially formulated strip of soft board material 86, which is CTE matched to the semiconductor material of the solar cells 84 and provides the cell-to-cell electrical connection with minimal losses. The strips of soft board material are bonded to a heat spreader 87, which is made up of a layer of graphite material. The heat spreader 87 is in turn bonded to a honeycomb aluminum base plate 88. The graphite material of the heat spreader 87 provides unsurpassed heat spreading capability and offer thermal conductivity up to 1500 W/mK as compared to about 200 W/mK for aluminum. The graphite weighs 60% less than aluminum and 82% less than copper.

FIG. 3A shows a prospective view of a medium concentration photovoltaic module 90, typically used in fixed installations, having eighteen concentrator cells held together by a metal frame 82. This module is similar to FIG. 3 module except it uses dome-shaped Fresnel lenses 92 to capture the sun rays 21 without tracking the sun. The dome shaped Fresnel lens provides a wide acceptance angle to sun rays and therefore no sun tracking will be required.

The design quality of the optical elements in a solar photovoltaic concentrator is the key to enable the exploitation of the efficiency potentials of multi-junction devices. The cells require homogeneous flux over the cell area and reproduction of the solar spectrum, for which the thickness of the layers was designed.

Lenses may be combined to form more complex optical systems. A typical Fresnel lens has a focal length that is about half of its diameter. For example a 10 inch diameter lens will have a 5 inch focal length. In order to design PV modules with thin practical frame similar to the normal PV panels, the condenser lens becomes impractically “fast”—that is, its diameter is greater than twice its focal length (≦f/0.5). To shorten the focal length, this invention uses two Fresnel lenses, grooves together, to form a two-lens element with a focal length equal to the geometric mean of the two focal lengths used in the pair. For example, if each lens has a 5 inch focal length, the pair will have an effective focal length of 2.5 inches. To avoid degradation, the 2 lenses have exactly the same groove density and that they are well centered with respect to each. The focal lengths need not be equal, so that conjugate ratios other than 1:1 are easily achieved.

The simplest case is when lenses are placed in contact. If 2 lenses of focal lengths f₁ and f₂ are “thin”, the combined focal length f of the lenses can be calculated from:

1/f=1/f₁+1/f₂

Since 1/f is the power of a lens, it can be seen that the powers of thin lenses in contact are additive. If two thin lenses are separated by some distance d, the distance from the second lens to the focal point of the combined lenses is called the back focal length (BFL). This is given by:

BFL=f₂(d−f₁)/[d−(f₁+f₂)]

Note that as d tends to zero, the value of the BFL tends to the value of f given for thin lenses in contact.

Using a combination of positive, negative and shaped non-imaging Fresnel lenses can result in concentration methods that result in shorter focal lengths.

FIG. 4 shows an example of sun concentrator optics 100 having 2 positive Fresnel lenses 83. The first lens bends the solar rays 21 towards its focal point and the second lens bends the rays further towards the solar cell 84 at a shorter focal point. This multi-lens method enables low, medium and high level of sun concentration. Up to 1000:1 sun concentration has been demonstrated. At high concentration levels, sun tracking is required to maintain efficiency. There are many low cost tracker suppliers that provide both active and passive sun trackers. The tracking systems track the sun to maximize energy production throughout the day. The secondary concentrator is used to increase the module acceptance angle and reduce the tracker accuracy.

FIG. 4A shows an example of concentrator optics 105 having one Fresnel lens 83 and one secondary reflective or refractive concentrator 85 used to create a homogenous flux for the solar cell 84. The secondary concentrator is also used to increase the module acceptance angle while tracking the sun. The acceptance angle with this design is expected to be between +/−0.5 and +/−1 degree. Without the secondary concentrator the acceptance angle of the module is less than +/−0.5 degree, which requires an accurate sun-tracker.

FIG. 4B shows an example medium concentrator optics 110 having one negative Fresnel lens 111 and one positive Fresnel lens 83. The first lens captures rays 21 from a wide angular area thus eliminating the need for tracking. The second lens bends the rays 21 towards the solar cell 84 near the focal point.

Low to medium sun concentration can be achieved even with fixed module installations. The dome shaped Fresnel lens used in the concentrator system is optimized as a low loss collector. A key breakthrough in the development of the dome-shaped lens was the successful injection molding of the lens. This process allows a rapid and inexpensive means for manufacturing high quality lenses for use in a concentrator system. FIG. 4C shows an example of a low to medium concentrator optics 120 having one dome-shaped Fresnel lens 92 and a flat Fresnel lens 111. The first lens captures sun rays 21 from a wide angular area thus eliminating the need for tracking. The second lens bends the rays towards the solar cell 84 near the focal point.

In order to reach their maximum efficiency, CPV cells require a uniform light distribution. In some case the Fresnel lenses may not be able to produce a uniform flux over the solar cell because of sun tracking errors, lens-to-solar cell misalignment or lens imperfection. FIG. 4D shows a secondary reflector/homogenizer system 125 that can be implemented with any CPV modules. The flux homogenizer 85 is used to redirect the rays 21 and create a uniform flux. Such device is known as a kaleidoscope. It consists of a hollow tube with plane sidewalls having reflective internal surfaces 129. Focused rays 21 from the Fresnel lens enter on one end of the kaleidoscope and undergo a number of reflections from the side walls 129 in order to create a more uniform intensity at the solar cells. The kaleidoscopes and their use in solar spectrum uniformity generation have been around for a long time and were subjects of many prior inventions. The key element in this is the addition of clear windows 127 made of low iron glass at the low end of the kaleidoscope to reduce the amount heat transferred directly to the solar cells. The concentrated heat in the kaleidoscope is dissipated through it metal body, which is heat sunk to the graphite heat spreader material. The homogenizer may be mounted directly above each of the solar cells 84 using the support legs 128, which are surface mountable using epoxy or solder. The other benefit of the homogenizer is its ability to increase the sun tracking angular error tolerance as shown in FIG. 4E, so that the tracker does not have to precisely track the sun. The homogenizer increases the module acceptance angle up to +/−1 degree.

The module packaging and its unique thermal management solution will now be described more fully hereinafter with references to the accompanying drawings, in which preferred embodiments of the invention are shown.

High sun concentration introduces heat. When sun radiation is concentrated, so is the amount of heat produced. Cell efficiencies decrease as temperatures increase, and higher temperatures also threaten the long-term stability of solar cells. Therefore, the solar cells must be kept cool in a concentrator system.

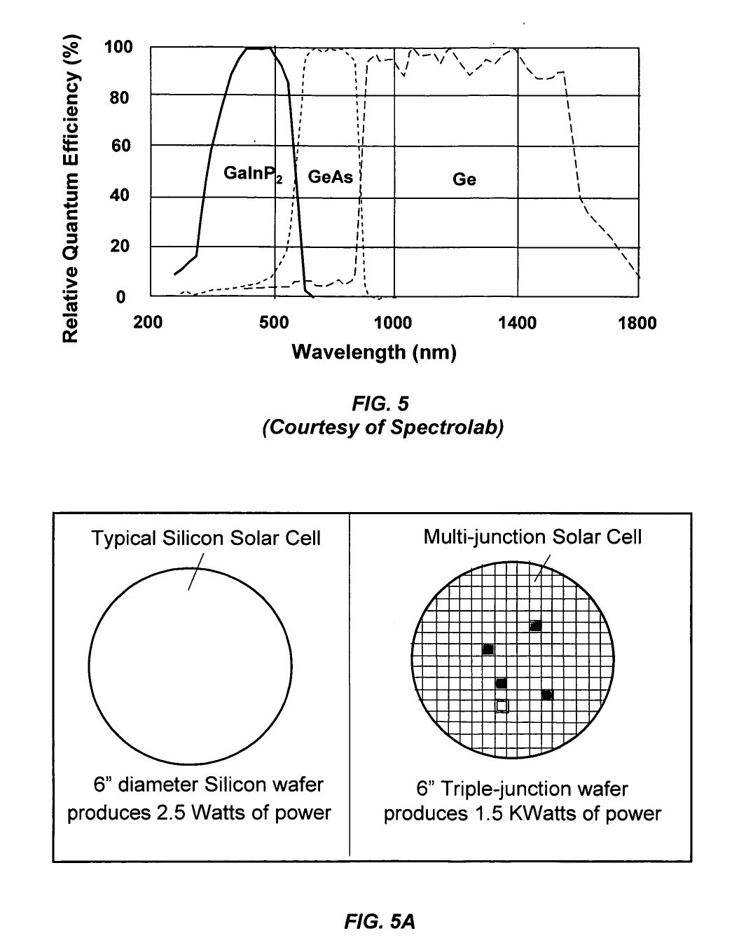

One of the main obstacles to sun concentration has been that the Silicon solar cells became very inefficient when exposed to concentrated sunlight. Silicon solar cells provide a best 15% efficiency under nominal conditions. In the last few years, new multi-junction solar cell technologies have emerged. The concentrator system described here uses triple junction solar cells with up to 40% efficiency, available from such companies as Spectrolab (a Boeing company). These multi-layer cells were commonly used on spacecrafts and satellites because of their high efficiency, but have been prohibitively expensive for terrestrial application. However, recent breakthroughs in this technology have made these cells more affordable. FIG. 5 (courtesy of Spectrolab) shows how the different semiconductor materials are used to capture a different part of the light spectrum and thereby achieving such high efficiency. The multi-junction cells capture solar rays from 400 nm to 1500 nm wavelengths. FIG. 5A shows a comparison between Silicon and multi-junction solar cell efficiency and electricity generation from a 6 inch wafer. The Silicon wafer generates about 2 to 2.5 watts, whereas the multi-junction wafer generates about 1.5 Kwatt of power.

The most critical issues in solar contractor module design are selection of material and process for mounting the solar cells to a cooling surface, achieving high thermal conductivity, and interconnecting the cells with very low electrical resistance.

The higher efficiency multi-junction cells are very small, typically ≦1 cm², as compared to Silicon cells used in traditional panels. The smaller size cells open the way to new packaging methods for solar concentrator modules with low cost materials. The main obstacle to achieving low cost packaging with good thermal conductivity has been the mismatch between the coefficient of thermal expansion (CTE) of semiconductor materials such as Si or GaAs, and good thermal metals such as aluminum and cooper.

The coefficient of thermal expansion of Silicon and other semiconductor multi-junction materials are between 4 and 7 parts-per-million per degree C. (ppm/deg C.). The CTE of low cost metal, such as aluminum and copper, are >16 ppm/deg C. For proper heat sinking, the solar cells must somehow be connected to a metal carrier or plate. Large CTE mismatch causes the semiconductor material to crack as the carrier material shrinks and expends are different rate over temperature. Traditionally, small semiconductor modules use CTE matched carrier material, such as copper tungsten (CuW) or aluminum silicon carbide (AlSiC). However, these materials are relatively expensive and provide no commercial viability for solar module fabrication.

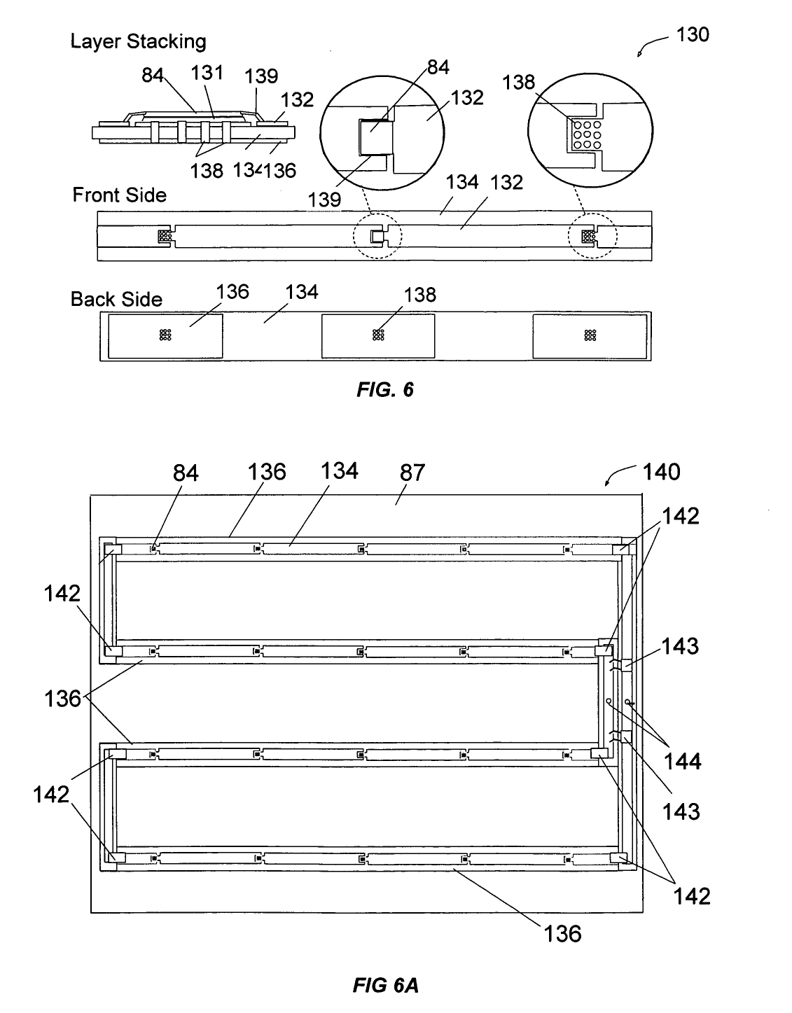

This invention uses a uniquely formulated thin PCB board of coefficient of thermal expansion (CTE) matched material to mount the solar cells, and then attaches the carrier board to the heat spreading material, which is attached to the housing. FIG. 6 shows details views 130 of the front and back sides of the CTE matched printed circuit board (PCB) strip with expanded views of the solar mounting areas and layer stacking. The multi-junction solar cells 84 are attached to the carrier PCB strip using solder or compliant conductive epoxy with high thermal coefficient 131, such the 6030-HK epoxy made by Diemat. The CTE matched board is made of a very low cost laminate material designed specifically for this application. The construction of the laminate provides exceptional mechanical stability and CTE matching to the solar cell's material. This laminate can be drilled, milled, and plated using standard methods for PTFE/woven fiberglass materials. It exhibits virtually no moisture absorption during fabrication processes. The soft board has one copper layer on the top 132, which may be gold or silver plated for better electrical conductivity, a thin layer of woven glass material 134, and a layer of copper in the bottom 136. Heat is transferred from the solar cell to the bottom layer using heat sink vias 138. The solar cell's positive posts are connected to the electrical traces 132 with special metal busses 139 that are bonded to the cell and to the electrical traces with solder or conductive epoxy.

One of the most important design considerations in the solar module is to minimize electrical resistance where the external electrical contacts carry off the current generated by the cell. Reducing electrical resistance is important in solar cells connectivity. The electrical connections must have extremely low loss. The best material to achieve this function is copper. For example, a 0.5 oz copper layer with a 25 mm width can provide cell-to-cell connections (250 mm apart) with less than 0.01 ohm resistance. Assuming that each cell generates 7 Amps of current at 2.8 Volts, the total voltage drop in the electrical trace will be <0.07 Volts and the total power dissipated in the line will be 0.5 Watts. FIG. 6A shows a top view of a 20-cell solar module electrical connectivity 140. The cells, which are mounted on the CTE matched board 136, are connected electrically through the copper traces 134. The CTE matched PCB is compression bonded to the heat spreader 87 and are connected to each other through the use of a wide metal strip 142, which is soldered or epoxy bonded at both ends. The 20 cells are divided into 2 groups of 10 cells each. Each group of 10 cells 84 are connected in series, therefore the output voltage will be additive. A bypass diode 143 is connected to each group. Since the current of a cell is proportional to its illumination, a shaded cell in series-connected module or string will “choke” the current through the other cells. To prevent this from happening, a bypass diode a placed across a fraction of cells in a module, in this case half of the cells in a module. In this way if a portion of the module is shaded, the bypass diode can “bypass” the current around those cells, preventing the “current choking” from happening. Unfortunately, the voltage drops to a fraction of a volt, greatly reducing the power available from the bypassed cells. Nonetheless, the total current through the module is not compromised and the output power of a partially shaded module might drop to half of its potential output, which is better than something close to zero. The positive and negative posts 144 are used to solder 2 wires (not shown) which will carry the DC current from the top of the PCB to the back of the solar module where the junction box (not shown) is located.

In one embodiment of this invention, a number of unique thermal-management methods using passive cooling systems are provided. The challenge is not only to remove heat from the sollar cell that is dissipating it, but also to get that heat to where you want it to go. The conventional approach is to employ a copper or aluminum heat spreader, often coupling it with a aheat sink or active liquid cooling, but this invention offers a passive alternative with lower weight plus directed heat flow. The general rule-of-thumb is that the concentrated heat created by the concentrating the sun must be spread over an area equal to or larger than the size of lens or collector. The most effective way to spread the heat from a small solar cell (1 cm²) over much large area is to use heat spreading materials with excellent longitudinal thermal conductivity.

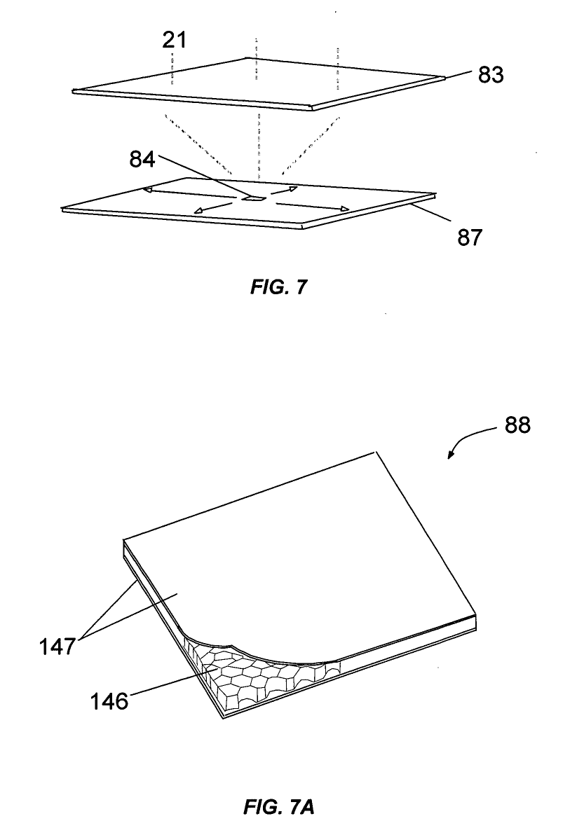

FIG. 7 shows the heat spreading concept of the current invention. In the case of refractive type concentrator, as the Fresnel lens 83 focuses the sun rays through the secondary concentrator 85 onto the solar cell 84 with up to 1000 times concentration, the heat from the sun is also focused on the small area of the solar cell. This invention's heat spreader 87 is made of graphite fibers, one of the newest types of heat-spreader materials. At 40% the weight of aluminum and 18% the weight of copper, graphite offers excellent thermal conductivity. The material is produced from expanded natural graphite flake, which is pressed and rolled out into long sheets and then cut to the required size for heat spreaders. This pliable spreader is anisotropic, conducting heat well along its x and y axes but less in the z-axis. As a result, it conducts the heat longitudinally away from the source. The graphite heat spreader enables radiation cooling equivalent to non-concentration temperature. The use of the graphite heat spreader in CPV modules is one of the key innovations in this invention. Thermal efficiency of the graphite heat spreader has been measured on practical samples CPV cells and have shown a temperature rise in the solar cells 20-to-30 degrees less than the temperature rise when an aluminum heat spreader is used, and 50 degrees lower than a ceramic carrier.

The sun concentrator module use the graphite material to spread the heat away from the solar cell towards the aluminum frame and thus minimize hot spots. By distributing heat evenly in two dimensions, heat spreaders eliminate “hot spots” while simultaneously reducing touch temperature in the third dimension. The graphite heat spreaders offer thermal conductivity up to 1500 W/mK as compared to about 200 W/mK for aluminum.

FIG. 7A shows an prospective view of the base plate 88, with a lift-up of the top layer. The base plate is made from aluminum honeycomb core 146 expanded into a hexagonal structure sandwiched by the aluminum facings 147 which are then bonded together by a layer of adhesive. Sandwich panels utilizing aluminum honeycomb cores result in lightweight, high strength structures that are very rigid and remain perfectly flat throughout their service life. Aluminum honeycomb panels have the best strength to weight ratio of any material available.

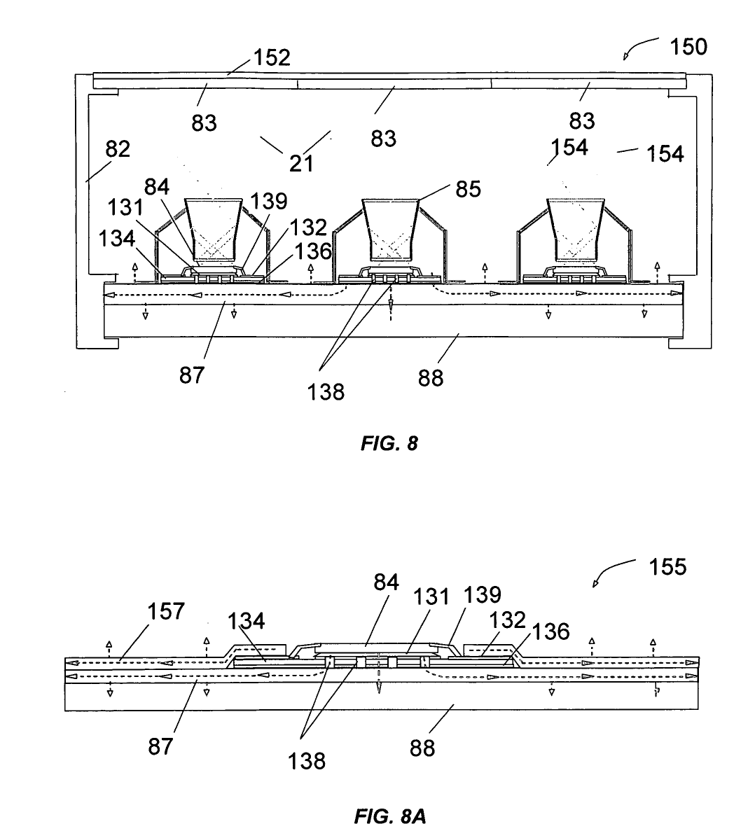

FIG. 8 is a cross-sectional view (not to scale) of 3 concentrator cells 150 illustrating the heat spreading method of the current invention. The Fresnel lenses 83, concentrate the sun rays 154 into a secondary concentrator 85 which creates a homogenous solar flux for the solar cells 84, which transforms the photons into electricity. The solar cell is attached to a PCB strip of CTE matched material using solder or compliant epoxy 131 with excellent thermal conductivity. The thermal vias 138 are used to transfer the heat from the solar cell to the heat spreader 87. The bottom of the CTE matched strip 136 is directly bonded to the graphite heat spreader 87 through compression. The heat transfer from the solar cell 84 to the frame 82 is shown with arrows. As previously discussed the heat transfer in the graphite material is mainly lateral and longitudinal. This method eliminates hot spots and allows the solar cell to remain relatively cool and thereby maintain its efficiency. Some of the heat is also dissipated in the base plate, which is also a great heat sink due to its honeycomb structure.

FIG. 8A is a cross-sectional view (not to scale) of a single concentrator cell 155 illustrating the double heat spreading method of the current invention. In addition to graphite heat spreader 87 under the solar cell, a second graphite heat spreader 157 is added on the top. The top heat spreader layer covers the entire top surface except for the areas where the solar cells are mounted. The solar cells are exposed to the concentrated solar energy from the Fresnel lenses through cut-out in the top graphite heat spreader layer. In addition to providing more heat spreading capability and removing the heat away from the solar cells, this top graphite layer also provides protection for the electrical connectivity layer 132 and keeps it relatively cool to minimize electrical loses.

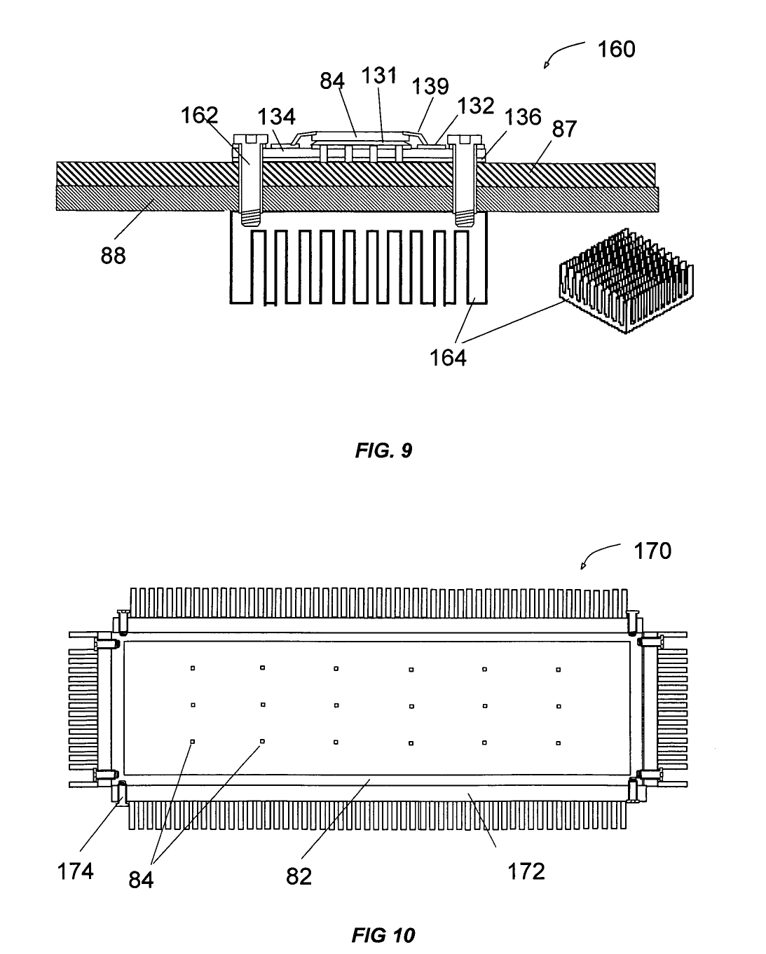

When additional solar module cooling is needed, then external heat sinks can be added underneath each of the solar cells or to the frame. A heatsink is a metallic device with high thermal conductivity. It increases the cooling surface area. FIG. 9 shows a cross sectional view of a solar cell with a heat sinks underneath it and an isometric view of the heatsink 160. The heatsink 164 attaches to the back plate under the solar cell, with screws 162. Using its large surface area, the heatsink lowers the cell's temperature by radiating its heat into the surrounding air. Heatsinks are made from an aluminum or copper alloy that has fins either shaped as parallel plates or with round, square, or elliptical pins. These heat sinks are commercially available at low cost.

FIG. 10 shows a top view of heatsinks added to the frame of an 18-cell solar module 170. The heatsink 172 are attached to the frame with screws 174. The heat sink will increase the surface area used to release the heat collected in the frame.

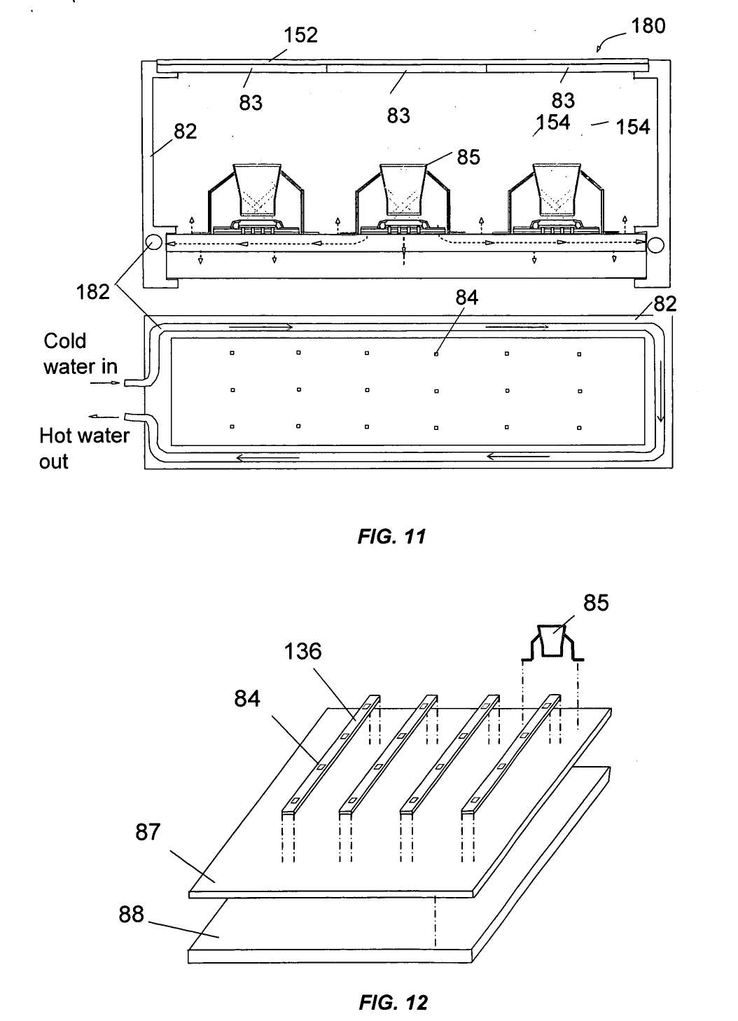

In addition to the above mentioned passive cooling techniques, a method for harvesting free hot water by actively circulating water through pipes embedded in the module's metal frame can be implemented. The hot water can be used for heating space in commercial and residential buildings. FIG. 11 Shows a cross sectional view 190 of a single solar cell and a top view of an 18-cell module with water cooling option. The water pipes 192, preferably made of cooper, are embedded in the module frame 82. Cold water enters the pipe from one end, circulates through the frame picking-up the heat and comes out hot at the other end.

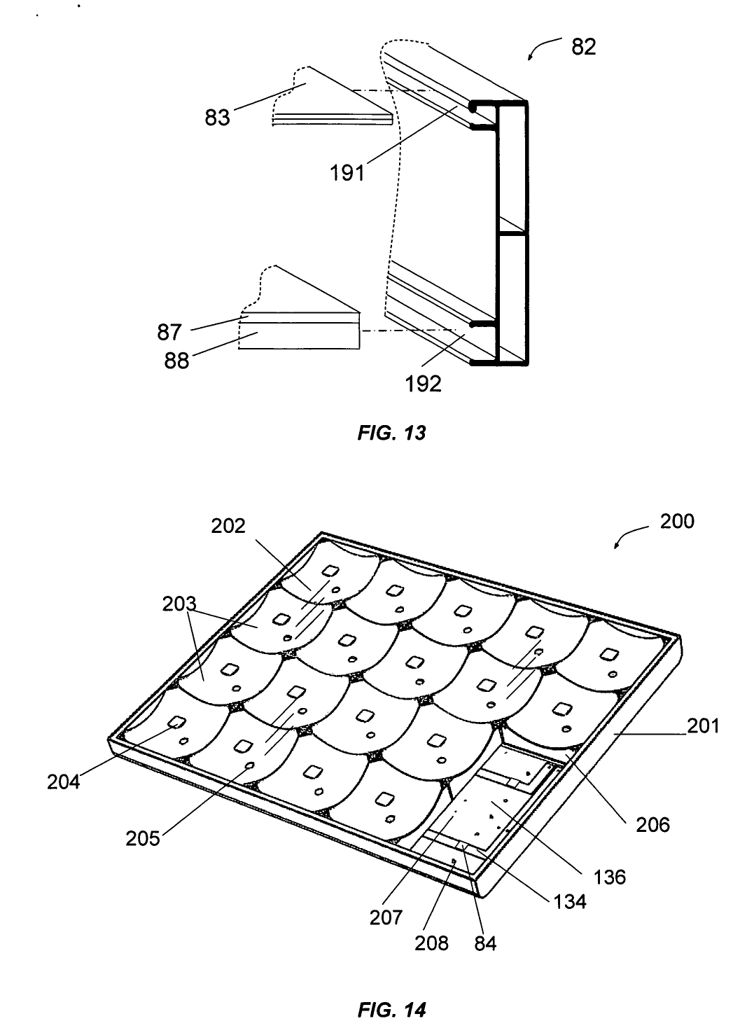

A brief description of a refractive type CPV module assembly method is now presented. The use of common materials and standard assembly methods makes this module highly attractive for manufacturing in any part of the world with no skilled labor. There are 2 main sub-assemblies in the refractive type CPV module, the concentrating optics and the generator circuit. In the optics sub-assembly, the Fresnel lenses are created out of a single sheet of optical acrylic material which is mounted directly to the module frame. In the signal generator subassembly shown in FIG. 12, the cells 84 are first attached to the carrier strip 136 by manual or automated methods. Next the heat spreader 87 is attached to the metal base plate 88 and then the carrier strips are compression bonded to the heat spreader. Finally the flux homogenizer 85 is attached to the heat spreader. Now the entire sub-assembly is ready to be mounted directly under the Fresnel lenses by attaching it to the frame shown in FIG. 13. The edge of the Fresnel lens 83 is inserted into the top slot 191, while the base sub-assembly, which includes the base plate 88 and the heat spreader 87, is inserted into the bottom slot 192.

Reflective-type CPV modules are not widely available today because of the lack of cost effective solar collectors and packaging methods. Also, mechanical structures for concentrating solar systems have been configured with bulky, box-type module construction and are difficult to manufacture, transport and install. This invention provide a unique approach to reflective-type CPV modules that eliminates the box-like look and integrates the collectors and solar cells into one simple highly efficient assembly that greatly reduces manufacturing costs.

Referring now to FIGS. 14-19, one embodiment of a reflective-type CPV module according to this invention is illustrated which may comprise several individual collectors 203 oriented side-by-side, as discussed below with reference to FIG. 14. The reflective-type CPV module 200 is initially generally described, followed by a discussion of individual aspects of the design.

The CPV solar module 200, as depicted in FIG. 14, includes a light weight housing tray 201, an anti-reflection glass cover 202, and a number of side by-side primary solar reflectors 203 each supported by a frame 206, an equivalent number of secondary reflectors 204, mounted to the bottom side of the protective glass 202 on top of the primary reflectors 203, a PCB board 136 holding all the solar cells 84 which are electrically connected to each other via copper traces 134, and heat spreaders (not shown) sandwiched between the PCB board 136 and the housing tray 201 and held in place by fasteners 208. The frames 206 are aligned to the solar cells 84 using alignment holes 207 in the PCB board 136. The primary reflectors 203 receive incident sunlight and reflect it to the secondary reflectors 204, which in turn reflect it onto multi-junction solar cells 84 located in a fixed position at the centerline of an opening 205 in the bottom of the primary reflector.

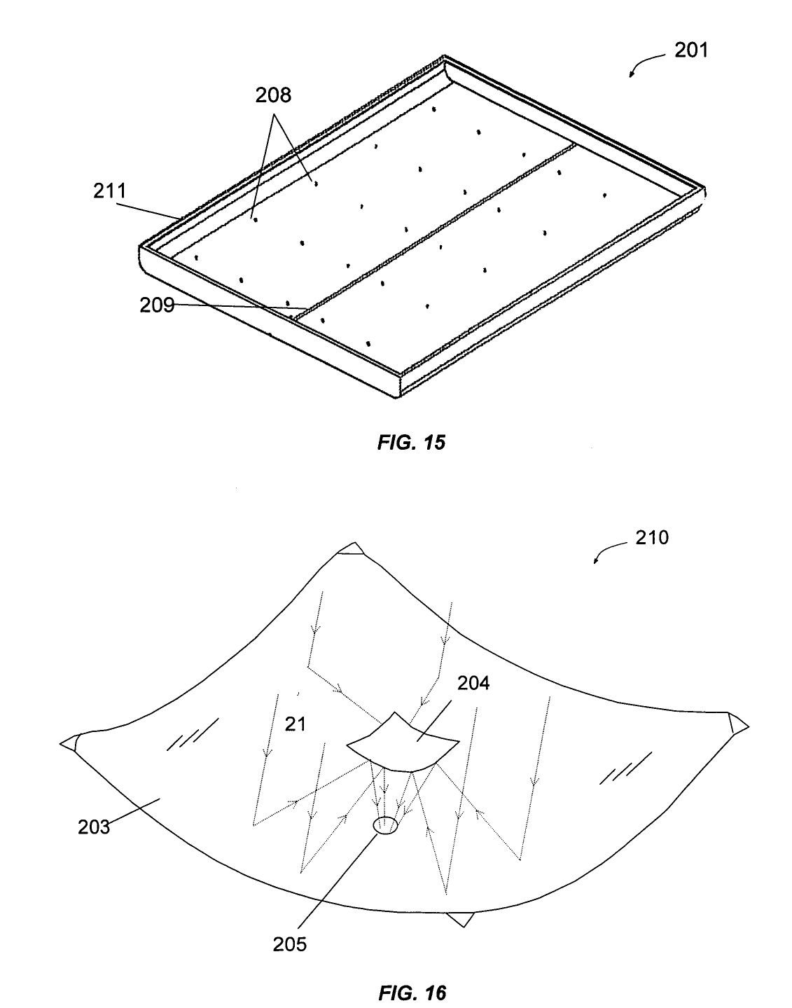

The housing tray 201, shown in FIG. 15, is preferably formed of aluminum or other light-weight, weather resistant and durable material. Tray stiffness is achieved by adding a small rib 209 to the bottom of the tray. Short bosses 208, which are used to hold the PCB carrier and the heat-spreader, are pressed to the bottom of the tray and act as fasteners for the PCB and heat-spreaders. The top side of the tray 201 has a flat edge 211, which is used to bond the top glass cover 202 to the tray 201.

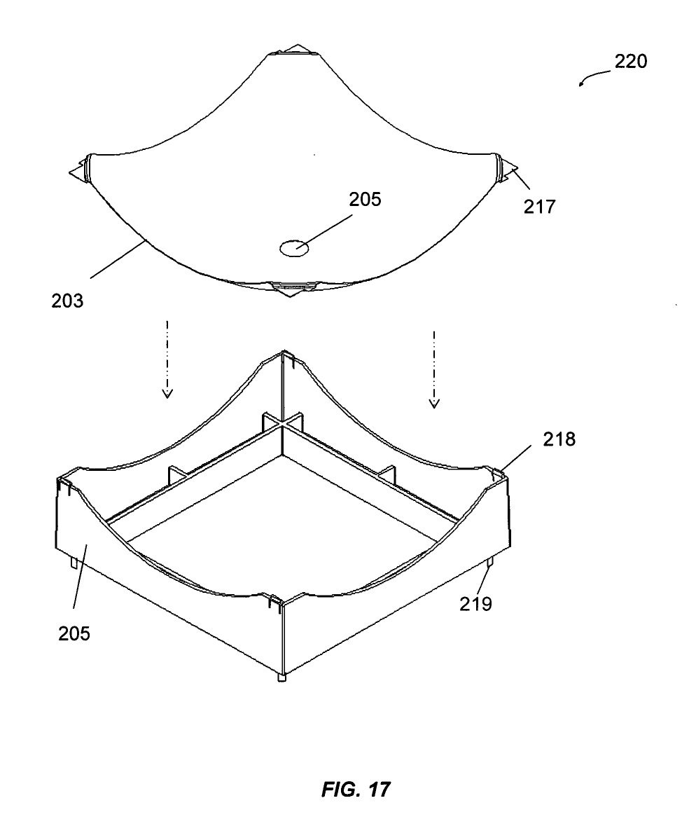

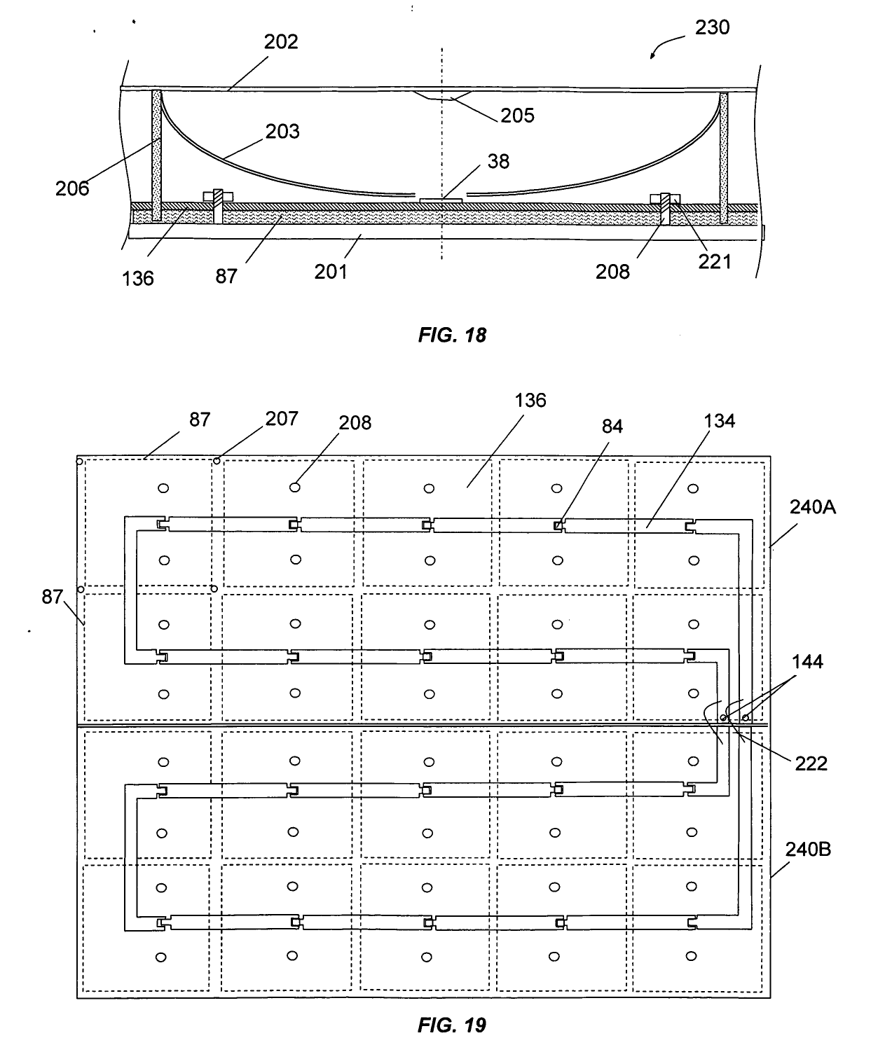

The primary and secondary reflectors collectively form the structure 210 for receiving incident sunlight 21 and reflecting it onto a multi-junction solar cell 84 located on the PCB board in a fixed position at the centerline of an opening 205 in the bottom of the primary reflector, as depicted in FIG. 16. The secondary reflector 204 is located above the primary reflector 203, as discussed below, and is bounded in that position to the protective glass 202, which covers the entire module top. The top surface of the reflector is preferably a highly-reflective, silver-metallized surface having high specular reflectance. Each primary collector 203 is supported by a frame 206 as shown in FIG. 17. The frame 206 is preferably made of light weight injection molded plastic material. The primary reflector 203 is attached to the frame 205 through a snapping mechanism 217 and 218. The frame is mounted above the solar cells 84 using legs 219 which get inserted into alignment holes 207 in the PCB board 136 and the heat spreader 87 which is secured on to the bottom of the tray using mounting bosses 208 and clamps 221 as shown in FIG. 18.

FIG. 19 shows a top view of a 20-cell PCB board pair 240A and 240B (left and right sides) of the current invention's reflective type CPV module. The solar cells 84, which are mounted on the CTE matched board 136, are connected electrically through the copper traces 134. The CTE matched PCB is compression bonded to the heat spreaders 87, which are located under the PCB board. The 20 cells are divided into 2 groups of 10 cells each. Each group of 10 cells 84 are connected in series, therefore the output voltage will be additive. The two halves are connected in parallel using bridge wires 222.

The positioning of the primary reflector 203 with respect to the secondary reflector 204, and the configuration of the secondary reflector 204, are both important in maximizing the efficiency of the reflector unit 210. The discussion that follows concerns this aspect of the present invention.

A parabola is a geometric shape defined by the locus of points that are equidistant from a point (the focus) and a focal line (directrix) that lie in the same plane. Reflective surfaces having the shape of a parabola have been commonly used in solar power collection systems because incident sunlight may be reflected to collection device located at the focus or directrix of the parabola. However, in order to achieve high efficiency, typical parabolic collectors have long focal length in the order of half of their diameter or side dimension. The unit 210 of the present invention (FIG. 16) is designed to take advantage of this property of a parabola, but in a much more efficient, shorter focal length, less expensive and practical manner than taught in the prior art.

In one presently preferred embodiment, the primary reflector 203 has a square parabola shape with 225 mm sides and 70 mm height. The secondary reflector 204 is approximately square with 36 mm sides and 10 mm height with a reflective surface in the shape of a hyperbola. The shape of the secondary is uniquely designed to provide a homogenous flux which improves the solar cells conversion efficiency. The exact geometry of the reflective surface is derived from the Cassegrain Equations for a primary parabolic-shaped reflective surface, which, in this instance, is the parabolic surface collectively formed by the primary collector, and a secondary hyperboloid reflective surface. The secondary reflector 204 may be constructed of machined or stamped aluminum having the appropriate shape noted above.

While various embodiments of the present invention have been shown and described here in, it will be obvious that such embodiments are provided by way of example only. Numerous variations, changes and substitutions may be made without departing from the invention herein. Moreover, when any range is understood to disclose all values therein and sub-ranges between any two numerical values with the range including the endpoints. Accordingly, it is intended that the invention be limited only by the spirit and scope of the appended claims.

What is claimed is:

1. A reflective-type Concentrating Photovoltaic (CPV) solar energy module, comprising:
a light weight housing tray;
an anti-reflection protective glass cover;
a number of support frames;
a number of primary solar collectors each having a reflective surface, said primary collectors being mounted inside said housing and supported in position by said frames to reflect sunlight incident on said reflective surface thereof;
a number of heat-spreader;
a printed circuit board mounted on top of said heat-spreaders;
a number of solar cells mounted on top of said printed circuit board and are electrically connected using copper traces on the said printed circuit board;
a number of secondary reflectors, each having a highly reflective surface, positioned on the bottom side of said anti-reflection glass so as to receive sunlight reflected from said primary reflectors and to reflect said sunlight onto said solar cells that convert solar energy to electricity.

2. The module of claim 1 in which said housing tray encloses a number of frames located side-by-side, each of said frames mounting a primary reflector;

3. The module of claim 1 in which said primary reflectors have parabolic shapes with shallow focal lines substantially coincident with said secondary reflectors;

4. The module of claim 1 in which said printed circuit board is made of material with a coefficient of thermal expansion (CTE) that is matched the said solar cells;

5. The module of claim 1 in which said printed circuit board has copper traces which provide low loss cell-to-cell electrical interconnections;

6. The module of claim 1 in which said anti-reflection protective glass has at least 95 percent transmissivity and less than 5 percent reflectivity;

7. The module of claim 1 in which said anti-reflection protective glass is also used to mount said secondary reflectors, which are permanently bonded to said protective glass above said primary reflectors

8. The module in claim 1 in which said solar cells are attached to said printed circuit board using solder or epoxy;

9. The module of claim 1 in which said heat-spreaders are formed of anisotropic material, conducting heat longitudinally away from said solar cells;

10. The module in claim 1 in which said heat spreaders are made of graphite fibers weighing substantially less than aluminum or cooper heat spreaders;

11. The module in claim 1 in which said heat spreaders are bonded directly to the bottom side of said PCB board below said solar cells;

12. The module in claim 1 in which said heat spreaders have thermal conductivity over 400 W/mK;

13. An efficient passive cooling system for Concentrating Photovoltaic (CPV) solar energy modules, comprising:
a light weight housing tray;
a number of heat-spreader mounted to the bottom of the said housing tray;
a thin printed circuit board (PCB) bonded to the top of said heat-spreaders;
a number of solar cells receiving concentrated solar energy from the sun and converting it to electricity;
a number of heatsink vias, in said PCB board, are used to transfer heat from the top layer where said solar cells are mounted to said heat spreaders and said housing tray;

14. The passive cooling system in claim 14 in which said heat-spreaders are formed of anisotropic material, conducting heat longitudinally with over 400 W/mK thermal conductivity;

15. The passive cooling system in claim 14 in which said printed circuit board is made of a thin laminate material with a coefficient of thermal expansion (CTE) that is matched to said solar cells;

16. The passive cooling system in claim 14 in which said heatsink vias are drilled into said PCB board, at said solar cells mounting locations, to conduct heat from the said solar cells to the said heat spreader;

17. A Cassegrain type reflective optics system for concentrating solar energy comprising:
a primary parabolic solar collectors having a highly reflective surface to reflect sunlight incident on it;
a convex secondary reflector having a highly reflective surface, positioned on top of said primary reflector so as to receive sunlight reflected from said primary reflector and to reflect said sunlight into a solar cell through an opening in the middle of said primary reflector;

18. The Cassegrain type collector in claim 18 in which said parabolic primary reflector has a complex concave surface characteristics resulting in focal point no greater than one third or its diameter or side dimension;

19. The Cassegrain type collector in claim 18 in which said secondary reflector has a complex convex surface characteristics resulting in homogenous concentrated solar flux which improves solar energy conversion efficiency.
